(19) United States
(12) Patent Application Publication
(10) Pub. No.: US 2024/0136187 A1
(43) Pub. Date: Apr. 25, 2024

(54) METHOD OF MANUFACTURING ELECTRONIC DEVICE USING CYCLIC DOPING PROCESS, AND ELECTRONIC DEVICE MANUFACTURED BY THE SAME

(71) Applicant: Research & Business Foundation SUNGKYUNKWAN UNIVERSITY, Suwon-si (KR)

(72) Inventors: Geun Young YEOM, Seoul (KR); Ki Hyun KIM, Suwon-si (KR); Ji Eun KANG, Yongin-si (KR); Seong Jae YU, Suwon-si (KR); You Jin JI, Suwon-si (KR); Doo San KIM, Haenam-gun (KR); Hyun Woo TAK, Yongin-si (KR); Yun Jong JANG, Seoul (KR); Hee Ju KIM, Suwon-si (KR); Ki Seok KIM, Incheon (KR)

(73) Assignee: Research & Business Foundation SUNGKYUNKWAN UNIVERSITY, Suwon-si (KR)

(21) Appl. No.: 18/382,209

(22) Filed: Oct. 19, 2023

(30) Foreign Application Priority Data
Oct. 20, 2022 (KR) 10-2022-0136802

(51) Int. Cl. H01L 21/04; H01L 21/683

(52) U.S. Cl. CPC H01L 21/046; H01L 21/6835

(57) ABSTRACT

One embodiment of the present invention provides a method of manufacturing an electronic device using a cyclic doping process including i) an operation of forming a unit transfer thin film including a two-dimensional material on a transfer substrate, ii) an operation of doping the unit transfer thin film in a low-damage doping process, iii) an operation of transferring the unit transfer thin film doped according to the operation ii) on a transfer target substrate, and iv) an operation of repeatedly performing the operations i) to iii) several times to reach a target thickness.

### CROSS REFERENCE TO RELATED APPLICATION

The present application claims priority to Korean Patent Application No. 10-2022-0136802, filed Oct. 21, 2022, the entire contents of which is incorporated herein for all purposes by this reference.

### BACKGROUND OF THE INVENTION

### Field of the Invention

The present invention relates to a method of manufacturing an electronic device including a doping process, and more specifically, to a method of manufacturing an electronic device, which uniformly performs doping throughout a target thickness through a cyclic doping process including doping and transfer.

### Description of the Related Art

A two-dimensional material is a material in which atoms form a crystal structure on a plane in a thickness (about 1 nm) of a single atomic layer. The two-dimensional material has the characteristics of varying electrical and optical properties depending on a thickness, and as electronic devices such as a semiconductor have recently become miniaturized to a level of several nm, much research is being conducted as a next-generation semiconductor material to replace and complement conventional silicon.

When the next-generation two-dimensional material is applied to cutting-edge electronic devices, there are issues such as a sophisticated thickness control technology, a large-area synthesis technology, and doping, and among them, the doping process is the most effective method to control the electrical characteristics of the two-dimensional material.

A conventional representative doping process applied to the electronic devices is ion implantation, which is a process of implanting specific impurities into a target substrate such as a semiconductor in the form of ions.

However, since the ion implantation process may implant ions into the target substrate with high energy and thus cause damage to the target substrate, there is a problem in that it is difficult to apply the ion implantation process to the two-dimensional material having a thickness of several nm.

In order to solve the above problem, doping of the two-dimensional material is performed in a manner that minimizes damage to the material through surface treatment processes, and representatively, research on reactive radical adsorption using plasma, spin coating using a solution, an immersion process, and a remote doping process has been conducted.

However, in the above-described surface treatment processes, since the doping effect is dominant near a surface, when a thickness of the material is a monolayer or more, there is a problem in that uniform doping is not possible inside the material.

For example, the related art document, Korean Patent Application Laid-Open No. 10-2016-0133959 (entitled “METHOD OF DOPING GRAPHENE BASED ON SUPPORT LAYER THROUGH ION IMPLANTATION) proposes a method of protecting a graphene from strong beam energy and doping the graphene layer by covering a support layer on graphene in order to minimize damage caused by ion implantation when doping the graphene layer, which is a two-dimensional material, but according to the structure disclosed by the related art document, there is a limitation in that uniform doping inside the material is not still possible when the thickness of the material is a monolayer or more in that doping is formed on only a surface of the graphene in contact with the support layer.

Therefore, there is a critical need for a method of manufacturing a cutting-edge electronic device, which may provide uniform doping characteristics inside the two-dimensional material at the same time without damage to the two-dimensional material.

### Documents of Related Art

(Patent Document 1) Korean Patent Application Laid-Open No. 10-2016-0133959

### SUMMARY OF THE INVENTION

The present invention has been made in efforts to solve and improve the conventional problems and is directed to providing a method of manufacturing an electronic device, which may provide uniform doping characteristics inside a two-dimensional material at the same time without damage to the two-dimensional material, and an electronic device manufactured by the same.

The object of the present invention are not limited to the above-described object, and other objects that are not mentioned will be able to be clearly understood by those skilled in the art to which the present invention pertains from the following description.

One embodiment of the present invention for achieving the object provides a method of manufacturing an electronic device using a cyclic doping process including i) an operation of forming a unit transfer thin film including a two-dimensional material on a transfer substrate, ii) an operation of doping the unit transfer thin film in a low-damage doping process, iii) an operation of transferring the unit transfer thin film doped according to the operation ii) on a transfer target substrate, and iv) an operation of repeatedly performing the operations i) to iii) several times to reach a target thickness.

The two-dimensional material in the operation i) may include any one or more selected from the group consisting of transfer metal chalcogenide, graphene, boron nitride, black phosphorus, and combinations thereof.

The transfer metal chalcogenide may include any one or more selected from the group consisting of molybdenum disulfide, tungsten diselenide, and combinations thereof.

The low-damage doping process in the operation ii) may include any one or more selected from the group consisting of a reactive radical adsorption process using plasma, a spin coating process, a solution immersing process, a remote plasma doping process, and combinations thereof.

The operation of transferring of the operation iii) may include a) an operation of forming a support layer on the unit transfer thin film doped according to the operation ii), b) an operation of removing the transfer substrate positioned under the doped unit transfer thin film, c) an operation of transferring the doped unit transfer thin film on the transfer target substrate, and d) an operation of removing the support layer positioned on the doped unit transfer thin film and performing surface treatment on a surface of the doped unit transfer thin film in a single process.

The support layer in the operation a) may include any one or more selected from the group consisting of polymethyl methacrylate, polydimethylsiloxane, and combinations thereof.

The operation d) may be performed by including any one or more selected from the group consisting of ion beam treatment using an inert gas, thermal treatment, and combinations thereof.

The ion beam treatment using the inert gas may use an argon gas and may be performed under a voltage condition of 5 to 50 eV.

The operation of transferring of the operation iii) may include a) an operation of forming a support layer on the unit transfer thin film doped according to the operation ii), b) an operation of removing the transfer substrate positioned under the doped unit transfer thin film, c) transferring the doped unit transfer thin film on the transfer target substrate, e) an operation of removing the support layer positioned on the doped unit transfer thin film, and f) an operation of performing surface treatment on a surface of the doped unit transfer thin film from which the support layer has been removed.

The support layer in the operation a) may include any one or more selected from the group consisting of polymethyl methacrylate, polydimethylsiloxane, and combinations thereof.

The operation of removing the support layer of the operation e) may be performed by acid treatment.

The operation of performing the surface treatment of the operation f) may include ion beam treatment using an inert gas.

The ion beam treatment using the inert gas may use an argon gas and may be performed under a voltage condition of 5 to 50 eV.

Another embodiment of the present invention for achieving the object provides an electronic device manufactured according to a method of manufacturing an electronic device using a cyclic doping process including i) an operation of forming a unit transfer thin film including a two-dimensional material on a transfer substrate, ii) an operation of doping the unit transfer thin film in a low-damage doping process, iii) an operation of transferring the unit transfer thin film doped according to the operation ii) on a transfer target substrate, and iv) an operation of repeatedly performing the operations i) to iii) several times to reach a target thickness, including a two-dimensional material, and having a plurality of uniformly doped unit transfer thin films laminated thereon.

Still another embodiment of the present invention for achieving the object provides a method of manufacturing a p-n junction semiconductor device including an operation of manufacturing an n-type electronic device having a structure in which one or more layers of unit transfer thin films doped by a cycling doping process to which an n-type dopant ion beam is applied are laminated, an operation of manufacturing a p-type electronic device having a structure in which one or more layers are laminated by sequentially applying an ion beam for forming a p-type branch and a p-type dopant ion beam, and an operation of manufacturing a p-n junction semiconductor device by separating the n-type electronic device or the p-type electronic device by transfer and then bonding the n-type electronic device and the p-type electronic device.

The operation of manufacturing the n-type electronic device may further include an operation of adjusting a thickness of the n-type electronic device manufactured by repeatedly performing the operation of transferring the n-type electronic device on the previously manufactured n-type electronic device.

The operation of manufacturing the p-type electronic device may further include an operation of manufacturing the unit transfer thin film in which the p-type branch is formed through ion beam treatment for forming a controlled p-type branch, and an operation of manufacturing the p-type electronic device by the substitution of atoms by the p-type dopant ion beam treatment.

The operation of manufacturing the p-type electronic device may further include an operation of adjusting a thickness of the p-type electronic device manufactured by repeatedly performing the operation of transferring the p-type electronic device on the previously manufactured p-type electronic device.

### BRIEF DESCRIPTION OF THE DRAWINGS

FIG. 1 is a flowchart illustrating a method of manufacturing an electronic device using a cyclic doping process according to one embodiment of the present invention.

FIG. 2 is a schematic diagram illustrating the method of manufacturing the electronic device using the cyclic doping process according to one embodiment of the present invention.

FIG. 3 is a schematic diagram specifically illustrating an operation of transferring in the method of manufacturing the electronic device using the cyclic doping process according to one embodiment of the present invention.

FIG. 4 is a view illustrating an example in which a two-dimensional semiconductor device to which the method of manufacturing the electronic device using the cyclic doping process according to one embodiment of the present invention is applied is manufactured.

FIG. 5 is a view illustrating a result of performing Raman spectroscopy on an embodiment in which the two-dimensional semiconductor material is laminated according to the method of manufacturing the electronic device using the cyclic doping process according to one embodiment of the present invention.

### DETAILED DESCRIPTION OF THE INVENTION

Hereinafter, the present invention will be described with reference to the accompanying drawings. However, the present invention may be implemented in various different foams and is not limited to embodiments described herein. In addition, in order to clearly describe the present invention in the drawings, components irrelevant to the description have been omitted, and throughout the specification, similar components have been denoted by similar reference numerals.

Throughout the specification, when a first component is described as being “connected to (joined to, in contact with, or coupled to)” a second component, this includes not only a case in which the first component is “directly connected” to the second component, but also a case in which the first component is “indirectly connected” to the second component with a third component interposed therebetween. In addition, when the first component is described as “including,” the second component, this means that the first component may further include the third component rather than precluding the third component unless especially stated otherwise.

The terms used in the specification are only used to describe specific embodiments and are not intended to limit the present invention. The singular expression includes the plural expression unless the context clearly dictates otherwise. In the specification, it should be understood that terms such as “comprise” or “have” are intended to specify that a feature, a number, a step, an operation, a component, a part, or a combination thereof described in the specification is present, but do not preclude the possibility of the presence or addition of one or more other features, numbers, steps, operations, components, parts, or combinations thereof in advance.

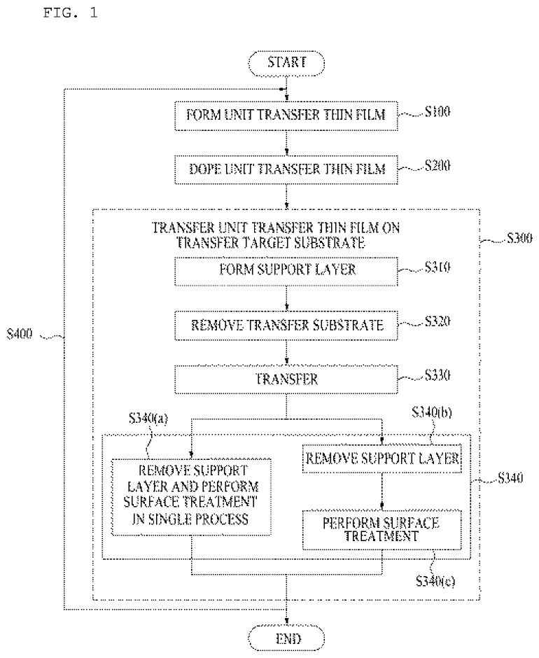

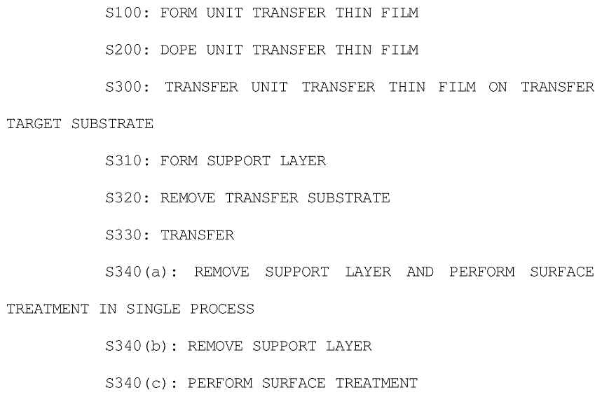

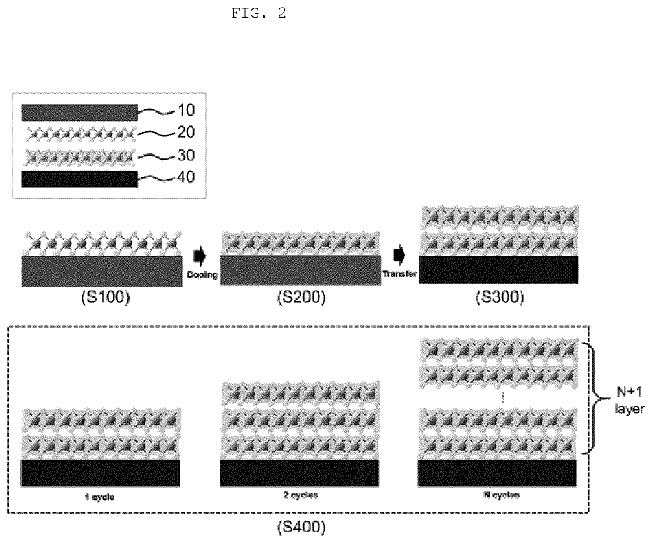

Hereinafter, a method of manufacturing an electronic device using a cyclic doping process according to one embodiment of the present invention will be described in detail with reference to FIGS. 1 and 2.

FIG. 1 is a flowchart illustrating a method of manufacturing an electronic device using a cyclic doping process according to one embodiment of the present invention.

FIG. 2 is a schematic diagram illustrating the method of manufacturing the electronic device using the cyclic doping process according to one embodiment of the present invention.

Referring to FIGS. 1 and 2, the method of manufacturing the electronic device using the cyclic doping process includes, as a configuration, i) an operation of foaming a unit transfer thin film 20 including a two-dimension material on a transfer substrate 10 (S100), ii) an operation of doping the unit transfer thin film 20 in a low-damage doping process (S200), iii) an operation of transferring a unit transfer thin film 30 doped according to the operation ii) on a transfer target substrate 40 (S300), and iv) an operation of forming the doped multi-layer unit transfer thin film 30 transferred above the transfer target substrate 40 by repeatedly performing the operations i) to iii) several times to reach a target thickness (S400).

Describing the reason why the embodiment has the above configuration, since the two-dimensional material, which is an object of a doping process in the present invention, is very thin as a material of which atoms form a crystal structure on a plane in a thickness of a single atomic layer, when ion implantation, which is a conventional doping technology, is used, serious damage to the thin film occurs.

Therefore, in order to perform doping on the thin film including the two-dimensional material, the low-damage doping process is essential. However, the conventionally used low-damage doping process has a limitation in that since a dopant is loaded or attached to the surface of the thin film in order to perform doping without damage to the thin film, when the thin film increases to a certain thickness or more, doping is performed locally on only the surface of the thin film.

The present invention effectively solves the problem by repeatedly performing the process of doping the unit transfer thin film 20 and the process of transferring the doped unit transfer thin film 30 on the transfer target substrate 40.

However, an electronic device manufactured by simply repeatedly laminating the doped unit transfer thin films 30 may have another cause of a degradation in performance caused by an interface problem between the laminated unit transfer thin films 20.

Therefore, in order to prevent the interface problem that may occur when transferring and laminating the unit transfer thin film 20, the present invention can effectively solve the problem by including an operation of performing surface treatment on an uppermost portion of the thin film laminated on the transfer target substrate 40 between unit processes including doping and transfer, which will be described below.

By including the above operations as the configuration, the present invention provides the method capable of manufacturing the electronic device having uniform doping characteristics inside the two-dimensional material even in the thickness of the monolayer or more at the same time without damage to the two-dimensional material of the unit transfer thin film 20.

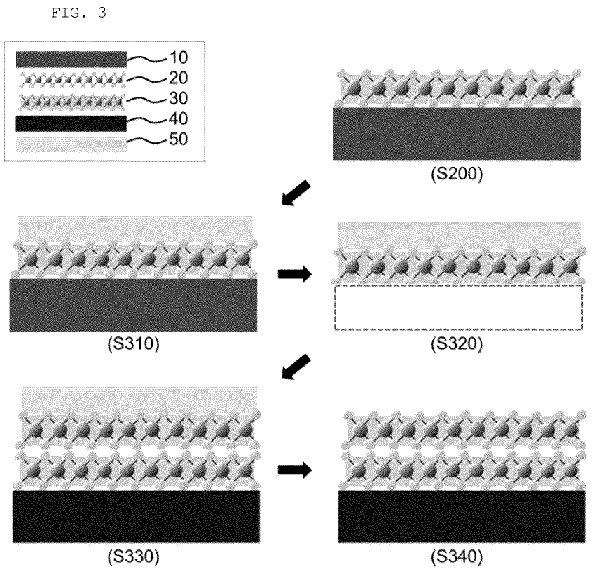

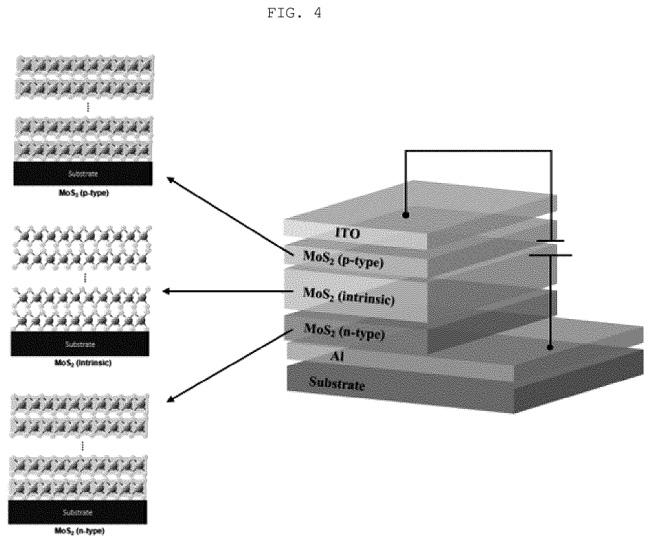

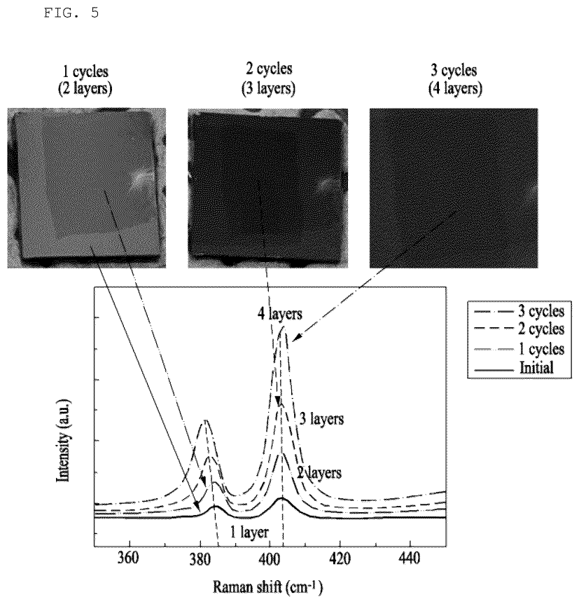

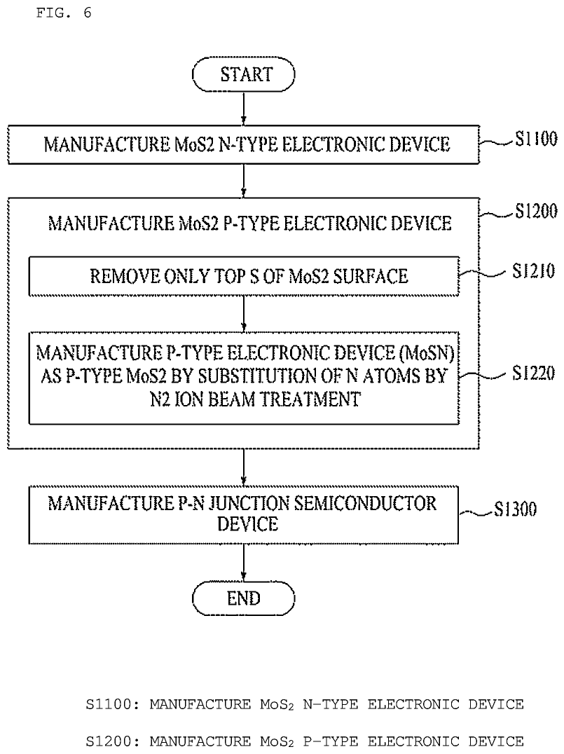

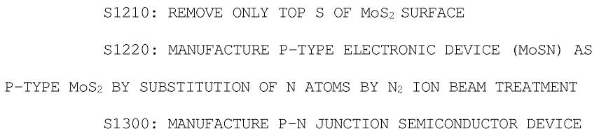

Hereinafter, each operation of the method of manufacturing the electronic device using the cyclic doping process according to the embodiment will be separately described in detail with reference to FIGS. 1 and 3.

FIG. 1 is a flowchart illustrating a method of manufacturing an electronic device using a cyclic doping process according to one embodiment of the present invention.

FIG. 3 is a schematic diagram specifically illustrating an operation of transferring in the method of manufacturing the electronic device using the cyclic doping process according to one embodiment of the present invention.

First, i) an operation of forming the unit transfer thin film 20 including the two-dimensional material on the transfer substrate 10 (S100) will be described.

The operation i) is an operation of foaming a thin film to be transferred on the transfer target substrate 40 and is an operation of forming the unit transfer thin film 20 including the two-dimensional material on the transfer substrate 10 (S100).

The method of forming the unit transfer thin film 20 may be construed as being formed through a typical thin film process used for forming the thin film in the art to which the present invention pertains.

For example, the method may be spin coating, low pressure chemical vapor deposition, normal pressure chemical vapor deposition, metal organic chemical vapor deposition, plasma chemical vapor deposition, inductively coupled plasma, atomic layer deposition, or plasma atomic layer deposition.

In the operation i), the transfer substrate 10 functions as a base when the unit transfer thin film 20 including the two-dimensional material is famed and is removed from the unit transfer thin film 20 in the subsequent transfer operation.

The transfer substrate 10 is not limited to a specific material as long as the unit transfer thin film 20 including the two-dimensional material may be formed on the transfer substrate 10.

For example, the material may be selected from the group consisting of SiO₂, Al₂O₃, HfO₂, LiAlO₃, MgO, Si, Ge, GaN, AlN, GaP, InP, GaAs, SiC, glass, quartz, sapphire, graphite, graphene, plastic, polymer, boron nitride (h-BN), and combinations thereof.

The transfer substrate 10 is not limited to a monolayer. As described above, in the transfer operation, the transfer substrate 10 is removed from the unit transfer thin film 20, and at this time, the multi-layer transfer substrate 10 may be formed according to a process method for removal.

For example, when a wet transfer process is used as the transfer method, the transfer substrate 10 has a double-layer structure (not illustrated) formed of a silicon layer and a silicon oxide layer positioned on the silicon layer, the silicon oxide layer is removed by acid treatment using hydrofluoric acid (HF) or the like in the transfer process, and the transfer substrate 10 and the unit transfer thin film 20 are separated.

Next, in the operation i), the two-dimensional material may include any one or more selected from the group consisting of transfer metal chalcogenide, graphene, boron nitride, black phosphorus, and combinations thereof. However, the two-dimensional material is not limited thereto, and any two-dimensional material having a laminated structure should be construed as applicable to the present invention.

In addition, the transfer metal chalcogenide may include any one or more selected from the group consisting of molybdenum disulfide, tungsten diselenide, and combinations thereof. However, the transfer metal chalcogenide is not limited thereto, and any transfer metal chalcogenide that may have a layered structure and may be easily obtained in the form of a two-dimensional monolayer due to weak bonding between layers should be construed as applicable to the present invention.

Next, ii) an operation of doping the unit transfer thin film 20 in the low-damage doping process (S200) will be described.

The operation ii) is an operation of doping the unit transfer thin film 20 formed on the transfer substrate 10 through the operation i) (S200). As described above, the doping should be pertained by the low-damage doping process to minimize damage caused by doping the thin film having a small thickness and including the two-dimensional material.

In this case, the low-damage doping process in the operation ii) may include any one or more selected from the group consisting of a reactive radical adsorption process using plasma, a spin coating process, a solution immersing process, a remote plasma doping process, and combinations thereof.

Next, an operation iii) is an operation of transferring and laminating the unit transfer thin film 30 doped according to the operation ii) on the transfer target substrate 40 and is an operation of performing surface treatment to solve the interface problem caused by lamination. A detailed description will be made below with reference to specific embodiments.

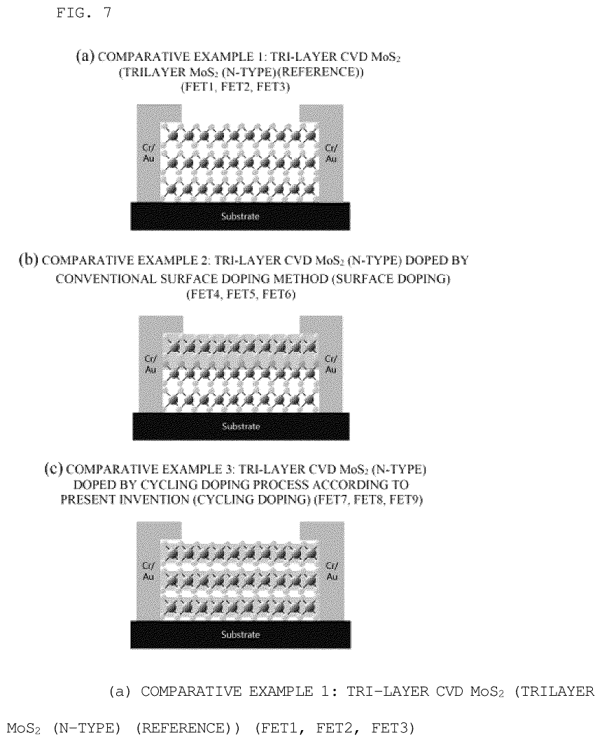

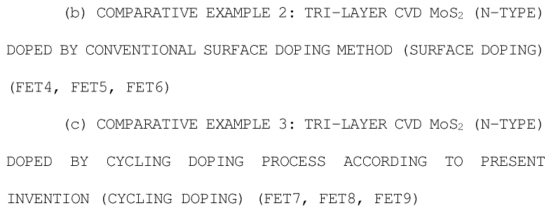

Next, iv) an operation of repeatedly performing the operations i) to iii) several times to reach the target thickness (S400) will be described with reference to FIG. 4.

FIG. 4 is a view illustrating an example in which a two-dimensional semiconductor device to which the method of manufacturing the electronic device using the cyclic doping process according to one embodiment of the present invention is applied is manufactured.

The operation iv) (S400) is an operation of repeatedly performing the operations i) to iii) several times to laminate the doped unit transfer thin film 30 on the transfer target substrate 40 to reach the target thickness to fit a device to be manufactured.

When repeatedly performing the operations i) to iii) several times, the doped unit transfer thin film 30 to be laminated is not limited to a thin film doped with the same material, and as illustrated in FIG. 4, may be laminated by varying a material doped on the doped unit transfer thin film 30.

In addition, the doped unit transfer thin film 30 to be laminated is not limited to the same size, and sizes between layers laminated using a patterning process commonly used in the art to which the present invention pertains may vary.

Next, iii) the operation of transferring the unit transfer thin film 30 doped according to the operation ii) on the transfer target substrate 40 (S300) will be described with reference to FIGS. 1 and 3.

FIG. 1 is a flowchart illustrating a method of manufacturing an electronic device using a cyclic doping process according to one embodiment of the present invention.

FIG. 3 is a schematic diagram specifically illustrating the operation of transferring (S300) in the method of manufacturing the electronic device using the cyclic doping process according to one embodiment of the present invention.

The operation of transferring (S300) of the operation iii) may be performed by using a thin film transfer method commonly performed in the art to which the present invention pertains.

For example, the operation of transferring (S300) may be performed by including any one or more selected from the group consisting of transfer using a printing technique, wet transfer, transfer using a heat release tape, and combinations thereof.

Hereinafter, specific embodiments of the operation iii) will be described in detail.

A first embodiment is an embodiment in which the operation of transferring (S300) of the operation iii) includes a) an operation of foaming a support layer 50 on the unit transfer thin film 30 doped according to the operation ii) (S200) (S310), b) an operation of removing the transfer substrate 10 positioned under the doped unit transfer thin film 30 (S320), c) an operation of transferring the doped unit transfer thin film 30 on the transfer target substrate 40 (S330), and d) an operation of removing the support layer 50 positioned on the doped unit transfer thin film 30 and perform surface treatment on the doped unit transfer thin film 30 in a single process (S340(a)).

First, a) the operation of forming the support layer 50 on the unit transfer thin film 30 doped according to the operation ii) (S310) will be described.

The operation a) (S310) is an operation of forming the support layer 50 on the doped unit transfer thin film 30 in order to transfer the doped unit transfer thin film 30 on the transfer target substrate 40.

Specifically, the support layer 50 is intended to enable the doped unit transfer thin film 30 to maintain a thin film even when the transfer substrate 10 positioned under the doped unit transfer thin film 30 is removed in the transfer process.

A material of the support layer 50 may include any one or more selected from the group consisting of polymethyl methacrylate, polydimethylsiloxane, and combinations thereof.

Next, b) the operation of removing the transfer substrate 10 positioned under the doped unit transfer thin film 30 (S320) will be described.

The operation b) is a process of removing the transfer substrate 10 positioned under the doped unit transfer thin film in order to transfer the doped unit transfer thin film 30 on the transfer target substrate 40.

In this case, the removal method should be performed by using the low-damage process to prevent damage to the doped unit transfer thin film 30.

The low-damage process may be a method of chemically melting the transfer substrate 10. For example, when the transfer substrate 10 has a double-layer structure foamed of the silicon layer and the silicon oxide layer positioned on the silicon layer, the silicon oxide layer positioned above the silicon layer may be removed by being melted using a diluted hydrogen fluoride (HF) solution. Therefore, the transfer substrate 10 may be removed without damage to the doped unit transfer thin film 30.

Next, c) the operation of transferring the doped unit transfer thin film 30 on the transfer target substrate 40 (S330) will be described.

The operation c) (S330) is an operation of transferring and laminating the doped unit transfer thin film 30 on the transfer target substrate 40, and the transfer method may be performed by including a method commonly performed to transfer a thin film in the art to which the present invention pertains.

For example, the transfer method may include any one or more selected from the group consisting of a method of coming the doped unit transfer thin film 30 into contact with the transfer target substrate 40, a method of applying a pressure to outer surfaces of the doped unit transfer thin film 30 and the transfer target substrate 40 based on surfaces in which the doped transfer thin film 30 and the transfer target substrate 40 are in contact with each other so as to be pressed, a method of applying an electric field to both ends of the doped unit transfer thin film and the transfer target substrate 40 based on the surfaces in which the doped transfer thin film 30 and the transfer target substrate 40 are in contact with each other, and combinations thereof, and the methods may be simultaneously or sequentially performed.

Next, d) the operation of removing the support layer 50 positioned on the doped unit transfer thin film 30 and performing surface treatment on the surface of the doped unit transfer thin film 30 in the single process (S340(a)) will be described.

Next, the operation d) (S340(a)) represents an embodiment in which the operation of removing the support layer 50 positioned on the doped unit transfer thin film 30 and performing the surface treatment on the surface of the doped unit transfer thin film 30 is performed in the single process.

In this case, the operation d) may be performed by including any one or more selected from the group consisting of ion beam treatment using an inert gas, thermal treatment, and combinations thereof.

Since the processes remove the support layer 50 and at the same time, improve the surface roughness of the doped unit transfer thin film 30, the interface problem between the doped unit transfer thin films 30 to be subsequently laminated is significantly eliminated.

For example, when the transfer process is performed by using a wet transfer method using polymethyl methacrylate (PMMA) as the support layer 50, the support layer 50 has been conventionally removed by using acetone, but at this time, the PMMA has not completely fly away and has remained on the surface, and the remaining PMMA has caused the interface problem in a subsequent process. Therefore, the manufactured device has been unstable and has caused a degradation in electrical characteristics.

On the other hand, when the support layer 50 is removed by the ion beam treatment using the inert gas as proposed in the present invention, no remaining support layer 50 is present due to the high energy of the ion beam, and at the same time, the surface of the doped unit transfer thin film 30 from which the support layer 50 has been removed becomes very clean and smooth by a high directionality of the focused ion beam.

Therefore, in the embodiment, there is an advantage in that the removal of the support layer 50 and the surface treatment are performed at the same time, thereby simplifying the process and reducing the cost for the process.

More specifically, the ion beam treatment using the inert gas may use argon as the inert gas and may be performed under a condition of 5 to 50 eV as an applied voltage for the ion beam.

This is because when the voltage applied to the ion beam is lower than 5 eV, the support layer 50 may not be completely removed, and when the voltage exceeds 50 eV, the doped unit transfer thin film may be damaged and thus may not have a desired thickness.

The thermal treatment is intended to remove the remaining polymer and may be performed at a temperature of 250° C. or higher.

Hereinafter, a second embodiment will be described.

In the second embodiment, in the method of manufacturing the electronic device using the cyclic doping process according to the present invention, the operation of transferring (S300) of the operation iii) includes a) the operation of forming the support layer 50 on the unit transfer thin film 30 doped according to the operation ii) (S310), b) the operation of removing the transfer substrate 10 positioned under the doped unit transfer thin film 30 (S320), c) the operation of transferring the doped unit transfer thin film 30 on the transfer target substrate 40 (S330), d) an operation of removing the support layer 50 positioned on the doped unit transfer thin film 30 (S340(b)), and e) an operation of performing surface treatment on the surface of the doped unit transfer thin film 30 from which the support layer 50 has been removed (S340(c)).

In the description, the operations a) to c), which are common to the first embodiment, should be construed in the same manner, overlapping descriptions will be omitted, and the operations e) and f), which differ from the operations in the first embodiment, will be mainly described.

The embodiment differs from the first embodiment in that the operation of removing the support layer 50 (S340(b)) of the operation e) and the operation of performing the surface treatment (S340(c)) of the operation f) are separated.

In the embodiment, since the operations e) and f) are performed separately, there is an advantage in that there are various process methods that may be selected to remove the support layer 50. In particular, there is an advantage in large-scale and commercial application in that the conventionally pertained process methods may be used as it is.

Specifically, the removal of the support layer 50 in the operation e) may be performed by the acid treatment.

In addition, the surface treatment of the operation f) may be performed by including the ion beam treatment using the inert gas.

This is because when the voltage applied to the ion beam is lower than 5 eV, the surface treatment may not be correctly performed, and when the voltage exceeds 50 eV, the doped unit transfer thin film 30 may have a damaged surface or may not have the desired thickness.

Hereinafter, still another embodiment of the present invention provides an electronic device which is manufactured by the method of manufacturing the electronic device using the cyclic doping process, includes the two-dimensional material, and having a plurality of uniformly doped unit transfer thin films 30 laminated thereon.

In one embodiment of the present invention, since the method of manufacturing the electronic device using the cyclic doping process is used, doping is uniformly performed throughout the manufactured electronic device, and thus there is an advantage in that the electrical characteristics are precisely controlled and uniform.

In addition, it can be easily expected that since interfacial defects are removed by the surface treatment included in the manufacturing method, the electrical and optical properties are stable.

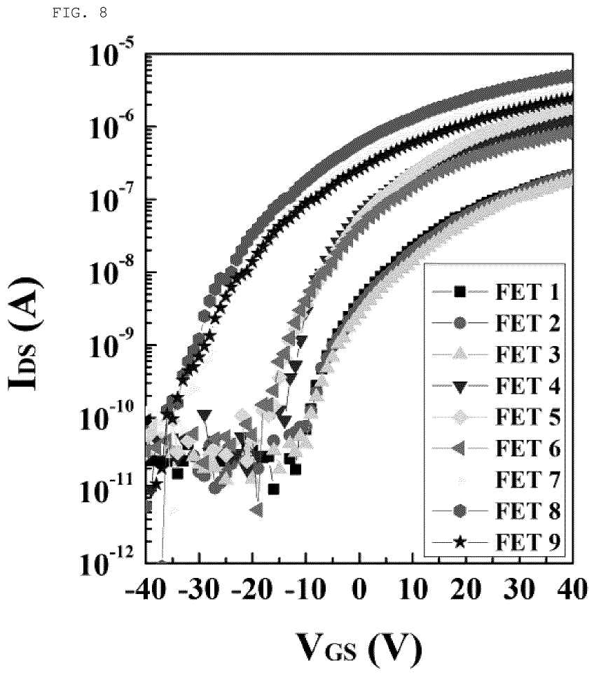

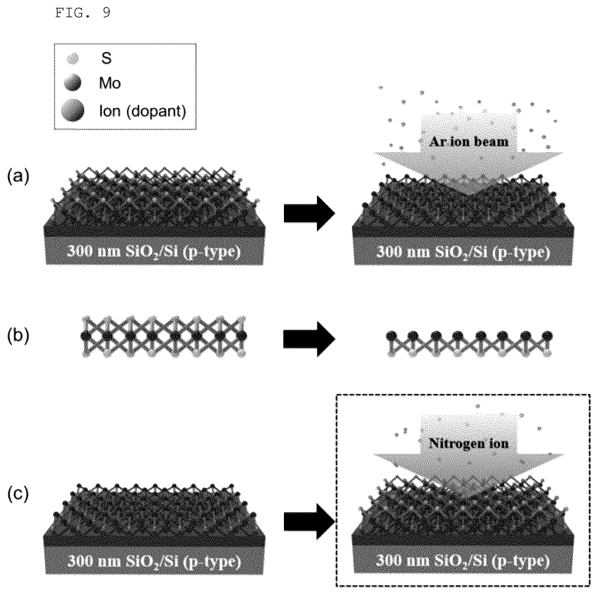

Another embodiment of the present invention provides a method of manufacturing a vertical or lateral p-n junction semiconductor device by applying a plasma doping process and the cycling doping process in FIGS. 1 to 5.

The method of manufacturing the p-n junction semiconductor device may include an operation of manufacturing an n-type electronic device having a structure in which one or more layers of the unit transfer thin films doped by the cycling doping process to which an n-type dopant ion beam is applied are laminated, an operation of manufacturing a p-type electronic device having a structure in which one or more layers are laminated by sequentially applying an ion beam for forming a p-type branch and a p-type dopant ion beam, and an operation of manufacturing a p-n junction semiconductor by separating the n-type electronic device or the p-type electronic device by transfer and then bonding the n-type electronic device and the p-type electronic device.

The operation of manufacturing the n-type electronic device may further include an operation of adjusting a thickness of the n-type electronic device manufactured by repeatedly performing the operation of transferring the n-type electronic device on the previously manufactured n-type electronic device.

The operation of manufacturing the p-type electronic device may further include an operation of manufacturing the unit transfer thin film on which the p-type branch is formed through the ion beam treatment for forming a controlled p-type branch, and an operation of manufacturing the p-type electronic device by the substitution of atoms by the p-type dopant ion beam treatment.

The operation of manufacturing the p-type electronic device may further include an operation of adjusting a thickness of the p-type electronic device manufactured by repeatedly performing the operation of transferring the p-type electronic device on the previously manufactured p-type electronic device.

FIGS. 6 to 9 are views illustrating an operation of manufacturing a MoS₂ n-type electronic device, a MoSN p-type electronic device, and a p-n junction semiconductor device by bonding the MoS₂ n-type electronic device and the MoSN p-type electronic device.

FIG. 6 is a view illustrating an operation of manufacturing a MoS₂ n-type electronic device, a MoSN p-type electronic device, and a p-n junction semiconductor device by bonding the MoS₂ n-type electronic device and the MoSN n-type electronic device.

As illustrated in FIG. 6, the method of manufacturing the p-n junction semiconductor device may include an operation of manufacturing the MoS₂ n-type electronic device (S1100), an operation of manufacturing the MoS₂ p-type electronic device (S1200), and an operation of manufacturing the p-n junction semiconductor device by bonding the MoS₂ n-type electronic device or the MoS₂ p-type electronic device (S1300).

The operation of manufacturing the MoS₂ n-type electronic device (S1100) may be an operation of manufacturing a CVD MoS₂ n-type electronic device having a multi-layer structure doped by the cycling doping process to which the remote chlorine plasma is applied. In this case, a thickness of the MoS₂ n-type electronic device manufactured by repeatedly performing the cycling doping process including the operation of forming the unit transfer thin film 20 in FIG. 1 (S100), the operation of doping the unit transfer thin film 20 (S200), and the operation of transferring the doped unit transfer thin film 30 on the transfer target substrate 40 may be adjusted. Here, the unit transfer thin film 20 may be made of MoS₂. In addition, the doped unit transfer thin film 30 may be a CVD n-type MoS₂ thin film having a multi-layer structure doped by the cycling doping process to which the remote chlorine plasma is applied.

Specifically, the thickness of the MoS₂ n-type electronic device manufactured by repeatedly performing the operations of manufacturing the MoS₂ n-type electronic device and transferring the manufactured MoS₂ n-type electronic device on the transfer target substrate may be adjusted.

The operation of manufacturing the MoS₂ p-type electronic device (S1200) may be an operation of manufacturing the MoS₂ p-type electronic device using ion beams having controlled energy and may include an operation of removing only a top S of MoS₂ (S1210) and an operation of manufacturing MoSN as the MoS₂ p-type electronic device (S1220).

The operation of removing only the top S of MoS₂ (S1210) may be an operation of removing only the top S of the MoS₂ surface through Ar ion beam treatment having controlled energy.

The operation of manufacturing MoSN as the MoS₂ p-type electronic device (S1220) may be an operation of manufacturing MoSN as the MoS₂ p-type electronic device by the substitution of N atoms by N₂ ion beam treatment.

In this case, a thickness of the MoSN p-type electronic device manufactured by repeatedly performing the cycling doping process including the operation of foaming the unit transfer thin film 20 in FIG. 1 (S100), the operation of doping the unit transfer thin film 20 (S200), and the operation of transferring the doped unit transfer thin film 30 on the transfer target substrate 40 may be adjusted. Here, the unit transfer thin film 20 may be made of MoS₂. In addition, the doped unit transfer thin film 30 may be MoSN.

Specifically, the thickness of the MoSN p-type electronic device manufactured by repeatedly performing the operations of manufacturing the MoSN p-type electronic device and transferring the manufactured MoSN p-type electronic device on the transfer target substrate may be adjusted.

The operation of manufacturing the p-n junction semiconductor device (S1300) may be an operation of manufacturing the vertical or lateral p-n junction semiconductor device by re-transferring the MoS₂ n-type electronic device and MoSN p-type electronic device transferred on the transfer target substrate 40, then bonding the MoS₂ n-type electronic device and the MoSN p-type electronic device, and removing the transfer substrate 10.

### Embodiment 3

Performance test of field effect transistors (FET) to which a tri-layer CVD MoS₂ n-type electronic device manufactured by the cycle doping process according to the embodiment of the present invention is applied

FIG. 7A is a view illustrating a tri-layer CVD MoS₂ n-type electronic device as Comparative Example 1, FIG. 7B is a view illustrating a CVD MoS₂ n-type electronic device doped by the surface doping method in the related art as Comparative Example 2, and FIG. 7C is a view illustrating a tri-layer CVD MoS₂ n-type electronic device doped by the cycling doping process according to the present invention as Embodiment 1.

FIG. 8 is a graph illustrating changes in drain source currents (I_{DS}(A)) according to gate source voltages (V_{GS}(V)) of field effect transistors FET1, FET2, and FET3 manufactured by applying the electronic device of Comparative Example 1 in FIG. 7A, field effect transistors FET4, FET5, and FET6 manufactured by applying the electronic device of Comparative Example 2 in FIG. 7B, and field effect transistors FET7, FET8, and FET9 manufactured by applying the electronic device of Embodiment 1 in FIG. 7C.

As illustrated in FIG. 7B, in the CVD MoS₂ n-type electronic device doped by the surface doping method in the related art, doping was dominant near the surface, and thus the proposed doping effect occurred in the multi-layer structure. Therefore, as illustrated in FIG. 7C, in the tri-layer CVD MoS₂ n-type electronic device doped by the cycling doping process to which the remote chlorine plasma was applied according to the embodiment of the present invention, it was confirmed that doping was uniformly performed in the multi-layer structure and the n-type doping effect was strong.

In addition, as illustrated in FIG. 8, it was confirmed that the field effect transistors FET7, FET8, and FET9 manufactured as the three-layer CVD MoS₂ n-type electronic device doped by the cycling doping process according to the embodiment of the present invention, which is Embodiment 1 in FIG. 7C, was significantly improved compared to the field effect transistors FET1, FET2, and FET3 manufactured by applying the electronic device in Comparative Example 1 and the field effect transistors FET4, FET5, and FET6 manufactured by applying the electronic device in Comparative Example 2 in terms of the effects of decreasing a threshold voltage and increasing a driving current (drain source current (I_{DS})) due to n-type doping.

### Embodiment 4

Manufacture of the tri-layer CVD MoS₂ p-type electronic device and the vertical/lateral p-n junction semiconductor device manufactured by the cycle doping process according to the embodiment of the present invention

FIG. 9 is a view illustrating a process of manufacturing the MoS₂ p-type electronic device by the cycling doping process according to one embodiment of the present invention.

The MoS₂ p-type electronic device in FIG. 9 was manufactured by the doping process using controlled plasma. In general, unlike the n-type doping process using the remote chlorine plasma in FIG. 7, the p-type branch is not formed by a method of simply adsorbing MoS₂ to the surface. In order to solve this problem, as illustrated in FIG. 9A, only the top S of the surface of a monolayer MoS₂ is removed as illustrated in FIG. 9B through Ar ion beam treatment in an ion beam system having controlled energy (MoS₂->MoS). Then, as illustrated in FIG. 9C, the p-type MoS₂ electronic device was manufactured by the substitution of N atoms by forming a MoSN compound through N₂ ion beam treatment having low energy.

Therefore, according to the present invention, by applying the remote chlorine plasma treatment in FIG. 7, the cycling doping process according to the embodiment of the present disclosure, and the method of manufacturing the p-type electronic device in FIG. 9 together and applying the method of manufacturing the p-n junction semiconductor device in FIG. 6, it is possible to manufacture the vertical or lateral p-n junction diode.

The above description of the present invention is for illustrative purpose, and those skilled in the art to which the present invention pertains will be able to understand that the present invention may be easily modified in other specific forms without changing the technical spirit or essential features thereof. Therefore, it should be understood that the above-described embodiments are illustrative and not restrictive in all respects. For example, each component described in a singular form may be implemented separately, and likewise, components described as being implemented separately may also be implemented in a combined form.

As the effect of the present invention according to the above configuration, it is possible to provide the uniform doping characteristics inside the two-dimensional material at the same time without damage to the two-dimensional material.

Since the doping characteristics of the electronic device manufactured accordingly are uniform throughout the electronic device, there is an advantage in that the electrical characteristics of the electronic device intended to be controlled by doping are uniform and stable throughout the electronic device.

In addition, since the electronic device is manufactured by transferring the thin film having the thickness of the monolayer, there is an advantage in that it is possible to manufacture the electronic device by precisely controlling the thickness of the electronic device.

It should be understood that the effects of the present invention are not limited to the above-described effects and include all effects inferable from the configuration of the invention described in the detailed description or claims of the present invention.

The scope of the present invention is defined by the claims to be described below, and all changes or modifications derived from the meaning and scope of the claims and equivalent concepts thereof should be construed as being included in the scope of the present invention.

### DESCRIPTION OF REFERENCE NUMERALS

10: transfer substrate 20: unit transfer thin film
30: doped unit transfer thin film 40: transfer target substrate
50: support layer

What is claimed is:

1. A method of manufacturing an electronic device using a cyclic doping process, comprising:
i) an operation of forming a unit transfer thin film including a two-dimensional material on a transfer substrate;
ii) an operation of doping the unit transfer thin film in a low-damage doping process;
iii) an operation of transferring the unit transfer thin film doped according to the operation ii) on a transfer target substrate; and
iv) an operation of repeatedly performing the operations i) to iii) several times to reach a target thickness.

2. The method according to claim 1, wherein the two-dimensional material in the operation i) includes any one or more selected from the group consisting of transfer metal chalcogenide, graphene, boron nitride, black phosphorus, and combinations thereof.

3. The method according to claim 2, wherein the transfer metal chalcogenide includes any one or more selected from the group consisting of molybdenum disulfide, tungsten diselenide, and combinations thereof.

4. The method according to claim 1, wherein the low-damage doping process in the operation ii) includes any one or more selected from the group consisting of a reactive radical adsorption process using plasma, a spin coating process, a solution immersing process, a remote plasma doping process, and combinations thereof.

5. The method of claim 1, wherein the operation of transferring of the operation iii) includes:
a) an operation of forming a support layer on the unit transfer thin film doped according to the operation ii);
b) an operation of removing the transfer substrate positioned under the doped unit transfer thin film;
c) an operation of transferring the doped unit transfer thin film on the transfer target substrate; and
d) an operation of removing the support layer positioned on the doped unit transfer thin film and performing surface treatment on a surface of the doped unit transfer thin film in a single process.

6. The method according to claim 5, wherein the support layer in the operation a) includes any one or more selected from the group consisting of polymethyl methacrylate, polydimethylsiloxane, and combinations thereof.

7. The method according to claim 5, wherein the operation d) is performed by including any one or more selected from the group consisting of ion beam treatment using an inert gas, thermal treatment, and combinations thereof.

8. The method according to claim 7, wherein the ion beam treatment using the inert gas uses an argon gas and is performed under a voltage condition of 5 to 50 eV.

9. The method of claim 1, wherein the operation of transferring of the operation iii) includes:
a) an operation of forming a support layer on the unit transfer thin film doped according to the operation ii);
b) an operation of removing the transfer substrate positioned under the doped unit transfer thin film;
c) transferring the doped unit transfer thin film on the transfer target substrate;
d) an operation of removing the support layer positioned on the doped unit transfer thin film; and
e) an operation of performing surface treatment on a surface of the doped unit transfer thin film from which the support layer has been removed.

10. The method according to claim 9, wherein the support layer in the operation a) includes any one or more selected from the group consisting of polymethyl methacrylate, polydimethylsiloxane, and combinations thereof.

11. The method of claim 9, wherein the operation of removing the support layer of the operation d is performed by acid treatment.

12. The method of claim 9, wherein the operation of performing the surface treatment of the operation e includes ion beam treatment using an inert gas.

13. The method of claim 12, wherein the ion beam treatment using the inert gas uses an argon gas and is performed under a voltage condition of 5 to 50 eV.

14. An electronic device manufactured according to claim 1, including a two-dimensional material, and having a plurality of uniformly doped unit transfer thin films stacked thereon.

15. A method of manufacturing a p-n junction semiconductor device, comprising:
an operation of manufacturing an n-type electronic device having a structure in which one or more layers of unit transfer thin films doped by a cycling doping process to which an n-type dopant ion beam is applied are stacked;
an operation of manufacturing a p-type electronic device having a structure in which one or more layers are stacked by sequentially applying an ion beam for foaming a p-type branch and a p-type dopant ion beam; and
an operation of manufacturing a p-n junction semiconductor device by separating the n-type electronic device or the p-type electronic device by transfer and then bonding the n-type electronic device and the p-type electronic device.

16. The method of claim 15, wherein the operation of manufacturing the n-type electronic device further includes an operation of adjusting a thickness of the n-type electronic device manufactured by repeatedly performing an operation of transferring the n-type electronic device on the previously manufactured n-type electronic device.

17. The method of claim 15, wherein the operation of manufacturing the p-type electronic device further includes:
an operation of manufacturing a unit transfer thin film on which a p-type branch is formed through ion beam treatment for forming a controlled p-type branch; and
an operation of manufacturing the p-type electronic device by the substitution of atoms by the p-type dopant ion beam treatment.

18. The method of claim 17, wherein the operation of manufacturing the p-type electronic device further includes an operation of adjusting a thickness of the p-type electronic device manufactured by repeatedly performing an operation of transferring the p-type electronic device on the previously manufactured p-type electronic device.
